(19) United States
(12) Patent Application Publication
(10) Pub. No.: US 2025/0069962 A1
(43) Pub. Date: Feb. 27, 2025

(54) SEMICONDUCTOR DEVICES AND METHODS OF MANUFACTURING SEMICONDUCTOR DEVICES

(71) Applicant: Amkor Technology Singapore Holding Pte. Ltd., Singapore (SG)

(72) Inventors: Mun Gil Ho, Gyeonggi-do (KR); Ho Seung Seo, Gyeonggi-do (KR); Won Bae Bang, Incheon (KR); Jin Young Khim, Seoul (KR); Sang Hyoun Lee, Incheon (KR); Ki Dong Sim, Gyeonggi-do (KR)

(73) Assignee: Amkor Technology Singapore Holding Pte. Ltd., Singapore (SG)

(21) Appl. No.: 18/453,191

(22) Filed: Aug. 21, 2023

(51) Int. Cl. H01L 23/053; H01L 21/52; H01L 21/56; H01L 23/00; H01L 23/31; H01L 23/498

(52) U.S. Cl. CPC H01L 23/053; H01L 21/52; H01L 21/56; H01L 23/3157; H01L 23/49822; H01L 23/49838; H01L 24/48; H01L 2224/48227

(57) ABSTRACT

In one example, an electronic device can comprise a substrate, a substrate sidewall over a side of the substrate. An electronic device can be disposed over the side of substrate and adjacent the substrate sidewall. An internal interconnect can be disposed between the electronic device and the substrate sidewall. An encapsulant can cover the internal interconnect between the electronic device and the substrate sidewall. A lid attach material can be disposed over the substrate sidewall and the encapsulant. A lid can be coupled to the encapsulant and the substrate sidewall by the lid attach material. A cavity can be defined between a bottom side of the lid and a top side of the electronic device. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example semiconductor device.

FIGS. 2A to 2H show an example method for manufacturing an example semiconductor device.

FIG. 3 shows a cross-sectional view of an example semiconductor device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” or “including,” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements For example, if element A is coupled to element B, then element A can be directly contacting element B or indirectly connected to element B by an intervening element C Similarly, the terms “over” or “on” may be used to describe two elements directly contacting each other or describe two elements indirectly connected by one or more other elements.

### DESCRIPTION

An example electronic device can comprise a substrate and a substrate sidewall over a side of the substrate. An electronic device can be disposed over the side of substrate and adjacent the substrate sidewall. An internal interconnect can be located between the electronic device and the substrate sidewall. An encapsulant can cover the internal interconnect between the electronic device and the substrate sidewall. A lid attach material can be disposed over the substrate sidewall and the encapsulant. A lid can be coupled to the encapsulant and the substrate sidewall by the lid attach material. A cavity can be defined between a bottom side of the lid and a top side of the electronic device.

Another example of an electronic device can comprise a substrate and a substrate sidewall over a side of the substrate. The substrate sidewall can comprise a dam protruding from the substrate sidewall away from the substrate. An electronic component can be disposed over the side of substrate and adjacent the substrate sidewall. An encapsulant can be located between the electronic device and the substrate sidewall. A lid attach material can be disposed over the substrate sidewall and the encapsulant. A lid can be coupled to the encapsulant and the substrate sidewall by the lid attach material. A cavity can be defined between the lid and the electronic device.

An example method of manufacturing an electronic device can comprise the steps of providing a substrate and providing a substrate sidewall over a side of the substrate. An electronic component can be provided over the side of the substrate and adjacent the substrate sidewall. An encapsulant can be disposed between the substrate sidewall and the electronic component. A lid attach material can be provided over the substrate sidewall and the encapsulant. The method can further comprise the step of providing a lid coupled to the substrate sidewall and the encapsulant by the lid attach material.

Other examples are included in the present disclosure. Such examples may be found in the figures, in the claims, or in the description of the present disclosure.

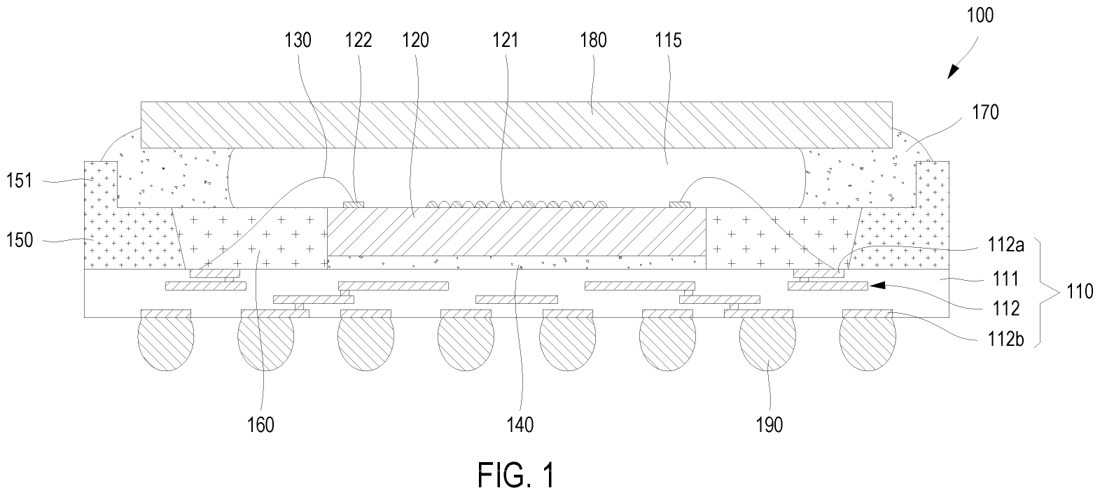

FIG. 1 shows a cross-sectional view of an example semiconductor device 100 In the example shown in FIG. 1, semiconductor device 100 can comprise substrate 110, electronic component 120, internal interconnects 130, die attach material 140, substrate sidewall 150, encapsulant 160, lid attach material 170, lid 180, and external interconnects 190.

Substrate 110 can comprise dielectric structure 111 and conductive structure 112. Conductive structure 112 can comprise substrate top terminals 112a and substrate bottom terminals 112b. Electronic component 120 can comprise transceiver 121 and component terminals 122 on a top side of electronic component 120. Substrate sidewall 150 can comprise substrate sidewall dam 151. In some examples, cavity 115 can be defined by the top side of encapsulant 160, the bottom side of lid 180, the bottom side of lid attach material 170, and the top side electronic component 120. Cavity 115 can be isolated from or separated from substrate sidewall 150 in some examples.

Substrate 110, electronic component 120, internal interconnects 130, die attach material 140, substrate sidewall 150, encapsulant 160, lid attach material 170, lid 180, and external interconnects 190 can be referred to as a semiconductor package and the package can provide protection for electronic component 120 from external elements or environmental exposure. The semiconductor package can provide electrical coupling between external electrical components and external interconnects 190.

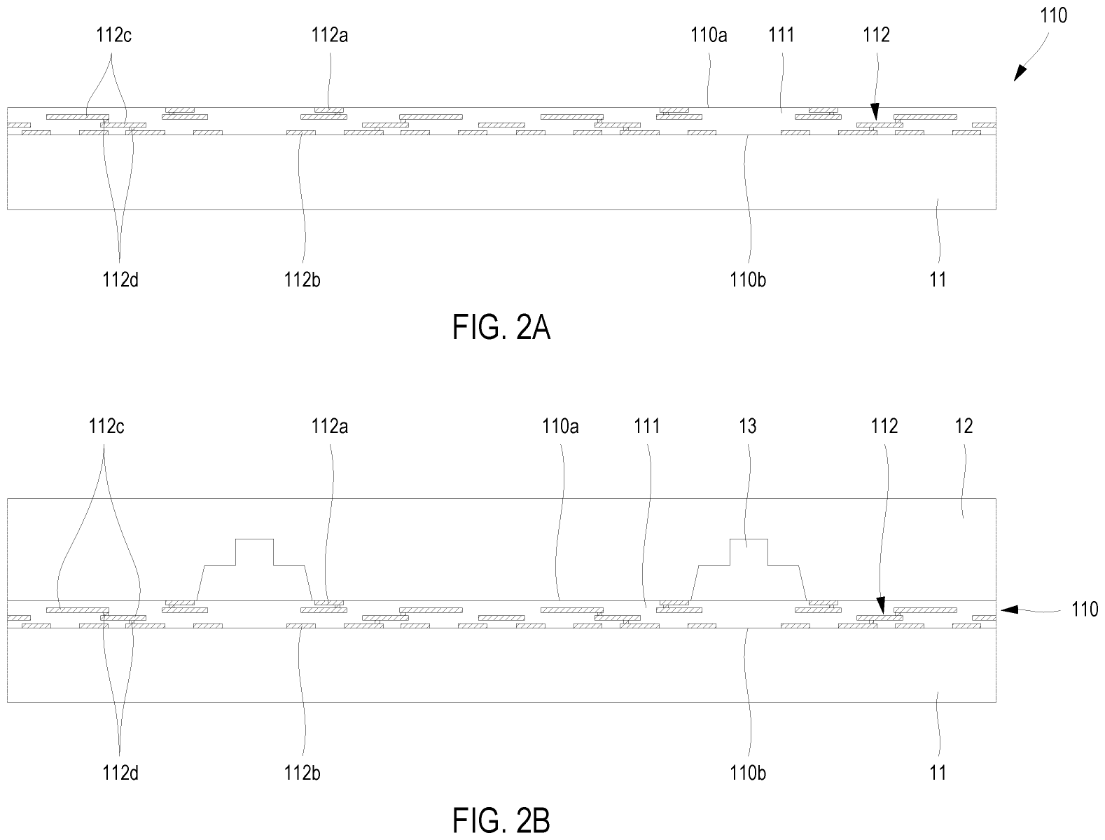

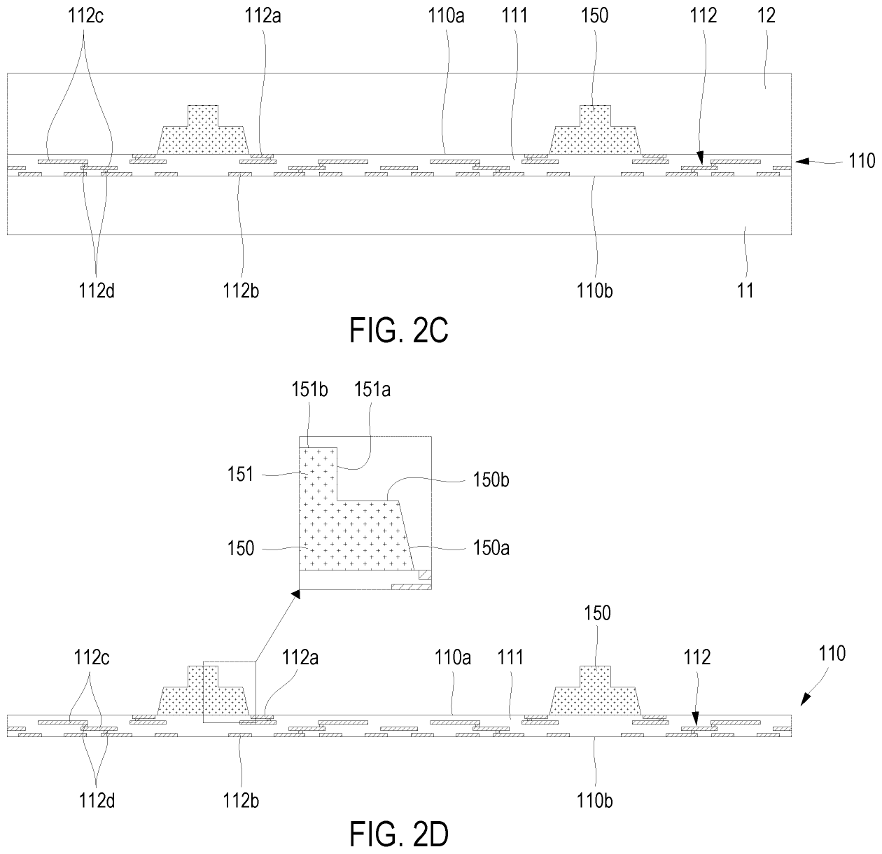

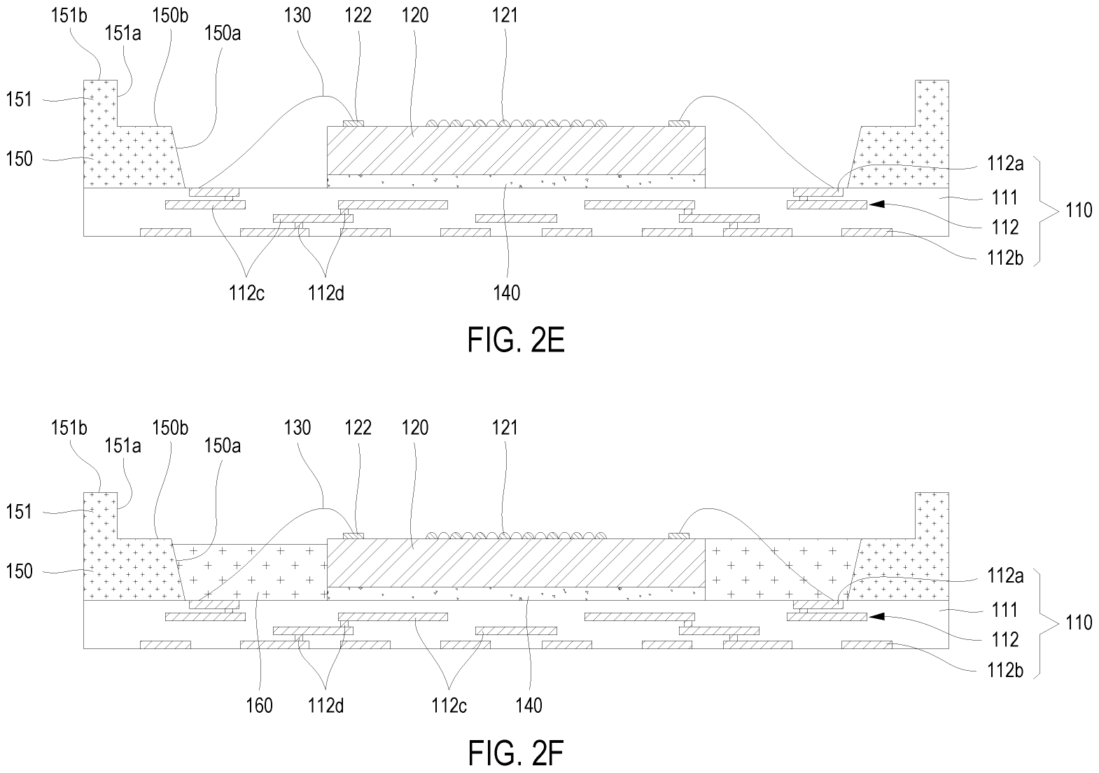

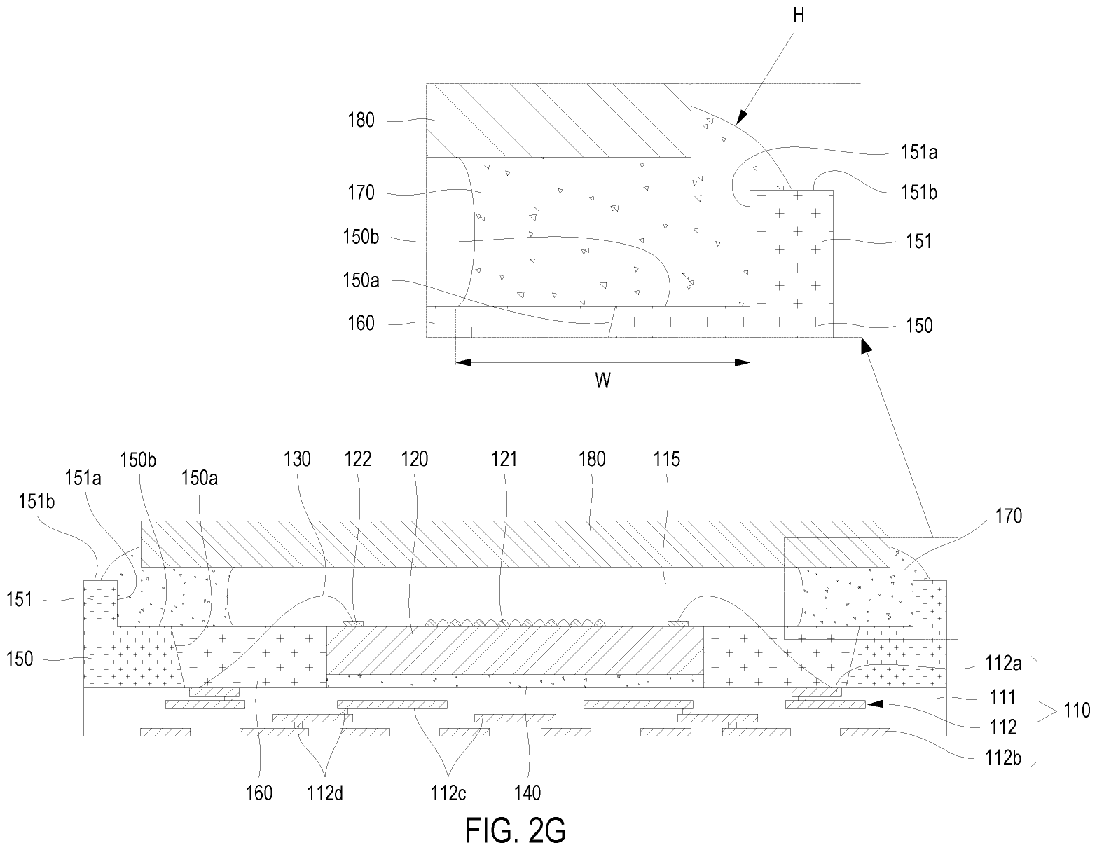

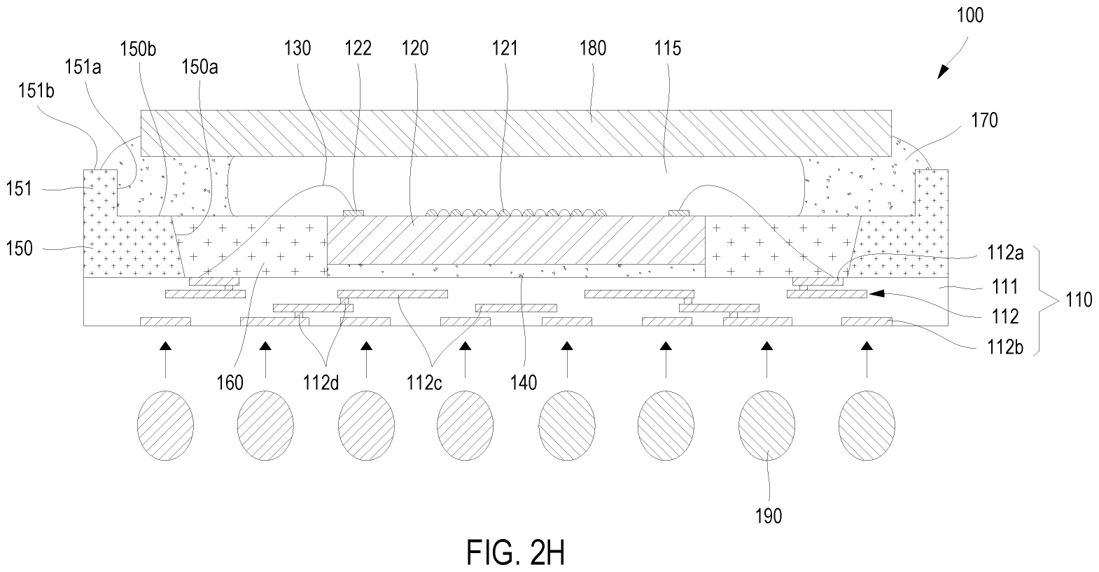

FIGS. 2A to 2H show an example method for manufacturing semiconductor device 100 FIG. 2A shows a cross-sectional view of semiconductor device 100 at an early stage of manufacture.

In the example shown in FIG. 2A, substrate 110 can be provided on bottom carrier 11. In some examples, bottom carrier 11 can comprise or be referred to as a planar plate or a chase. Bottom carrier 11 can be made of metal, plastic, or ceramic. In some examples, bottom carrier 11 can comprise a bottom chase of a mold apparatus.

Substrate 110 can comprise or be referred to as a rigid printed circuit board, a flexible printed circuit board, a laminate substrate, a redistribution layer (RDL) substrate, a coreless substrate, a ceramic substrate, a glass substrate, a silicon substrate, or a package substrate. In some examples, the thickness of substrate 110 can range from about 100 μm (micrometers) to about 1000 μm. Substrate 110 can couple electronic component 120 to an external device or protect electronic component 120 from an external environment.

Substrate 110 can comprise substantially planar substrate top side 110a, substantially planar substrate bottom side 110b opposite to substrate top side 110a, dielectric structure 111, and conductive structure 112. Electronic component 120 via die attach material 140, substrate sidewall 150, or encapsulant 160 can be attached to substrate top side 110a in a later process. External interconnects 190 can be attached to substrate bottom side 110b in a later process.

Dielectric structure 111 can comprise or be referred to as one or more dielectric layers. Dielectric structure 111 can comprise a prepreg material, Ajinomoto Buildup Film (ABF), a resin, FR4 (a laminate of copper foil-glass fiber fabric-copper foil), bismaleimide triazine (BT), polyimide (PI), benzocyclobutene (BCB), polybenzoxazole (PBO), or ceramic. In some examples, the thickness of dielectric structure 111 can range from about 25 μm to about 400 μm. In some examples, the thickness of dielectric structure 111 can refer to individual layers of dielectric structure 111. In some examples, the combined thickness of layers of dielectric structure 111 can be similar to or equal to the thickness of substrate 110. Dielectric structure 111 can maintain the shape of substrate 110 and can also support conductive structure 112.

Conductive structure 112 can comprise or be referred to as one or more conductive layers, traces, pads, patterns, under bumped metal (UBM). Conductive structure 112 can comprise copper, aluminum, gold, silver, nickel, palladium, or an alloy. In some examples, the thickness of conductive structure 112 can range from about 10 μm to about 72 μm. In some examples, the thickness of conductive structure 112 can refer to individual layers of conductive structure 112. In some examples, the combined thickness of layers of conductive structure 112 can be similar to or equal to the thickness of substrate 110. Conductive structure 112 can provide an electrical signal path (e.g., a vertical path or a horizontal path) for electronic component 120.

Conductive structure 112 can comprise substrate top terminal 112a, substrate bottom terminal 112b, embedded trace 112c, and embedded via 112d. Substrate top terminal 112a can be provided at the top side of dielectric structure 111 (or substrate 110). Substrate top terminal 112a can be exposed from the top side of dielectric structure 111. Substrate top terminal 112a can be coupled to embedded trace 112c or embedded via 112d. Substrate top terminal 112a can comprise or be referred to as a trace, a bond finger, a pad, a land, a stud bump, or UBM. Substrate top terminal 112a can comprise copper, aluminum, gold, silver, nickel, palladium, or an alloy. In some examples, the thickness of substrate top terminal 112a can range from about 10 μm to about 72 μm. Electronic component 120 can be coupled to the substrate top terminal 112a in a later process.

Substrate bottom terminal 112b can be provided on the bottom side of dielectric structure 111 (or substrate 110). Substrate bottom terminal 112b can be exposed from the bottom side of dielectric structure 111. Substrate bottom terminal 112b can be coupled to embedded trace 112c or embedded via 112d. Substrate bottom terminal 112b can comprise or be referred to as a trace, a pad, a ball land, or UBM. Substrate bottom terminal 112b can comprise copper, aluminum, gold, silver, nickel, palladium, or an alloy. In some examples, the thickness of substrate bottom terminal 112b can range from about 10 μm to about 72 μm. In some examples, external interconnect 190 can be coupled to substrate bottom terminal 112b in a later process.

Embedded trace 112c can be provided in a form extending in a generally horizontal direction inside dielectric structure 111 (optional). Embedded trace 112c can guide an electrical connection path in a substantially horizontal direction inside dielectric structure 111, and can be coupled to substrate top terminal 112a, substrate bottom terminal 112b, or embedded via 112d. In some examples, the thickness of embedded trace 112c can range from about 10 μm to about 72 μm. Embedded via 112d can be provided in a form extending in a substantially vertical direction inside dielectric structure 111 (optional). Embedded via 112d can guide an electrical connection path in a substantially vertical direction inside dielectric structure 111 and can be coupled to substrate top terminal 112a, substrate bottom terminal 112b, or embedded trace 112c. In some examples, the width of embedded via 112d can range from about 65 μm to about 350 μm.

Substrate 110 can be manufactured in a variety of ways. In some examples, taking a two-layer FR4 substrate as an example, substrate 110 can be manufactured by the steps of: machining a drill hole to couple a bottom copper foil and an top copper foil; performing electroplating on the drill hole to couple the bottom copper foil and the top copper foil; patterning an outer layer comprising a top terminal and a bottom terminal on the inner side (top side) and outer side (bottom side) of the substrate by providing a photosensitive film on the side of the substrate and photo-etching the photosensitive film so the sides of the bottom copper foil and the top copper foil are patterned; providing a seed layer for plating that is thinner than the thickness of the outer circuit, on the entire top and bottom sides of the substrate so as to cover the outer circuit, by electroless plating; providing a photosensitive film on the seed layer for plating to cover the seed layer for plating, and photo-etching the photosensitive film to pattern the seed layer for plating; providing a solder resist layer on the entire top and bottom sides of the substrate so as to expose the outer circuit; and forming a plating layer on the outer circuit comprising the inner terminal and the top outer terminal exposed outside of the solder resist layer, by applying electricity to the plating seed layer.

In some examples, when a three-to-six-layer substrate has more than two layers, the substrate can be made by using an inner-layer circuit and a laminating step in addition to the above-described process. As an example, the inner-layer circuit can be provided by photo-etching a photosensitive film to pattern the sides of the top copper foil and the bottom copper foil for each substrate, thereby patterning the inner layer circuit on the bottom and top sides of each substrate. In some examples, the dielectric structure can be a B-stage prepreg, and, after the lamination step, the dielectric structure turns into a C-stage state, and thus, each substrate can be integrated to then provide one multilayer substrate. In some examples, after the lamination step, a hole processing step, a plating step, an outer layer circuit providing step, and the like, can be sequentially provided similarly as described above.

Substrate 110 can be provided in the form of a matrix or strip having multiple rows and columns. Substrate 110 can have rows and columns and can be provided in a circular wafer shape, square panel shape, or rectangle panel shape. Thus, substrate 110 can be individually separated during the manufacturing process of semiconductor device 100.

In some examples, substrate 110 can be a pre-formed substrate The pre-formed substrate can be manufactured prior to attachment to an electronic device and can comprise dielectric layers between respective conductive layers The conductive layers can comprise copper and can be formed using an electroplating process The dielectric layers can be relatively thicker non-photo-definable layers that can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF) The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate omitting the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process.

In other examples, substrate 110 can be a redistribution layer (“RDL”) substrate RDL substrates can comprise one or more conductive redistribution layers and one or more dielectric layers that (a) can be formed layer by layer over an electronic device to which the RDL substrate is to be coupled, or (b) can be formed layer by layer over a carrier that can be entirely removed or at least partially removed after the electronic device and the RDL substrate are coupled together RDL substrates can be manufactured layer by layer as a wafer-level substrate on a round wafer in a wafer-level process, or as a panel-level substrate on a rectangular or square panel carrier in a panel-level process RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, or (b) fan-in electrical traces within the footprint of the electronic device The conductive patterns can be formed using a plating process such as, for example, an electroplating process or an electroless plating process. The conductive patterns can comprise a conductive material such as, for example, copper or other plateable metal The locations of the conductive patterns can be made using a photo-patterning process such as, for example, a photolithography process and a photoresist material to form a photolithographic mask The dielectric layers of the RDL substrate can be patterned with a photo-patterning process, which can include a photolithographic mask through which light is exposed to photo-pattern desired features such as vias in the dielectric layers Thus, the dielectric layers can be made from photo-definable organic dielectric materials such as, for example, polyimide (PI), benzocyclobutene (BCB), or polybenzoxazole (PBO) Such dielectric materials can be spun-on or otherwise coated in liquid form, rather than attached as a pre-formed film. To permit proper formation of desired photo-defined features, such photo-definable dielectric materials can omit structural reinforcers or can be filler-free and without strands, weaves, or other particles, that could interfere with the light from the photo-patterning process In some examples, such filler-free characteristics of filler-free dielectric materials can permit a reduction of the thickness of the resulting dielectric layer Although the photo-definable dielectric materials described above can be organic materials, in other examples the dielectric materials of the RDL substrates can comprise one or more inorganic dielectric layers Some examples of inorganic dielectric layer(s) can comprise silicon nitride (Si3N4), silicon oxide (SiO2), or SiON. The inorganic dielectric layer(s) can be formed by growing the inorganic dielectric layers using an oxidation or nitridization process instead using photo-defined organic dielectric materials Such inorganic dielectric layers can be filler-fee and without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate.

FIG. 2B shows a cross-sectional view of electronic device 100 at a later stage of manufacture. In the example shown in FIG. 2B, top carrier 12 can be provided on substrate 110. Top carrier 12 can comprise or be referred to as a planar plate or a chase. Top carrier 12 can be made of metal, plastic, or ceramic. In some examples, top carrier 12 can comprise a top chase of the mold apparatus. Top carrier 12 can comprise cavity 13 through which substrate sidewall 150 can be provided in a later process. As top carrier 12 is clamped on substrate 110, a space or a gap corresponding to cavity 13 can be provided on substrate 110.

FIG. 2C shows a cross-sectional view of electronic device 100 at a later stage of manufacture. In the example shown in FIG. 2C, a resin (e.g., substrate sidewall 150) can be inserted into the space on substrate 110 (e.g., into cavity 13 of FIG. 2B of top carrier 12). In some examples, the resin can be provided by a transfer molding manner. The transfer molding manner can be a method in which a fluid resin is cured after supplying the fluid resin from a gate (supply port) of a mold to cavity 13. In some examples, the resin can comprise EMC (Epoxy Molding Compound), filler-reinforced polymer, B-stage pressed film, gel. After the resin curing process, bottom carrier 11 and top carrier 12 can be separated from substrate 110.

FIG. 2D shows a cross-sectional view of electronic device 100 at a later stage of manufacture. In the example shown in FIG. 2D, substrate sidewall 150 can be provided on substrate 110 after the resin curing process. In some examples, as substrate 110 comprises additional resin, substrate 110 can be referred to as a pre-molded PCB. In some examples, substrate sidewall 150 can serve as a stiffener. In some examples, substrate sidewall 150 can comprise substrate sidewall dam 151 according to the shape of cavity 13 provided in top carrier 12. In some examples, a width of substrate sidewall dam 151 can be less than a width of substrate sidewall 150. In some examples, substrate sidewall 150 can comprise sloped side 150a and planar top side 150b. Planar top side 150b can also be referred to as a ledge. In some examples, substrate sidewall dam 151 can protrude from a side of substrate sidewall 150 distal from substrate 110. In some examples, substrate sidewall dam 151 can also comprise planar vertical side 151a and planar top side 151b. Planar vertical side 151a can meet planar top side 151b at a right angle, though some examples of planar vertical side 151a can meet planar top side 151a at an obtuse angle. Planar vertical side 151a can thus be sloped at a pitch similar to sloped side 150a.

In some examples, substrate sidewall 150 and substrate sidewall dam 151 can be referred to as a step mold structure or a trench mold structure. In some examples, the thickness of substrate sidewall 150 or substrate sidewall dam 151 can range from about 320 μm to about 370 μm. In some examples, substrate sidewall 150 or substrate sidewall dam 151 can support lid 180 via lid attach material 170 in a later process. In some examples, substrate 110, substrate sidewall 150, and substrate sidewall dam 151 can be sawn with a diamond wheel or laser beam in a later process. Thus, lateral sides of substrate 110, substrate sidewall 150, and substrate sidewall dam 151 can be coplanar.

FIG. 2E shows a cross-sectional view of electronic device 100 at a later stage of manufacture. In the example shown in FIG. 2E, electronic component 120 can be provided on substrate 110. Electronic component 120 can be adjacent sidewall substrate 150. In some examples, electronic component 120 can be attached on substrate 110 through die attach material 140 such as an adhesive, a film, or an epoxy. In some examples, electronic component 120 can be attached onto die attach material 140 after die attach material 140 is provided on substrate 110. In some examples, die attach material 140 can be attached onto substrate 110 after die attach material 140 is provided on electronic component 120.

Electronic component 120 can be coupled to substrate 110 through internal interconnects 130 such as Au (gold) wire or Cu (copper) wire. Electronic component 120 can comprise transceiver 121 to receive or transmit electromagnetic signals including infrared light, visible light, ultraviolet light, or laser beam. In some examples, transceiver 121 can comprise or be referred as micro-lens array or laser emitter. Electronic component 120 can comprise component terminals 122 to couple substrate 110. In some examples, component terminals 122 can comprise or be referred to as Al bond pads. Internal interconnects 130 can couple component terminals 122 of electronic component 120 to substrate top terminals 112a of substrate 110. In some examples, the diameter of internal interconnects 130 can range from about 12.7 μm to about 50.8 μm.

Electronic component 120 can comprise or be referred to as a semiconductor die, a semiconductor chip, a semiconductor package, a semiconductor device, an active component, or a passive component. In some examples, electronic component 120 can comprise a CIS (CMOS Image Sensor), a laser diode, a LED (Light-Emitting Diode), or MEMS (Micro Electromechanical Systems). In some examples, electronic component 120 can comprise a digital signal processor (DSPs), a network processor, a power management unit, an audio processor, a wireless baseband system on a chip (SoC) processor, a sensor, an application specific integrated circuit, a memory, an antenna on package (AoP), an antenna in package (AiP), a 5G NR mmWave module, a sub-6 GHz RF module or an integrated passive device (IPD). In some examples, the thickness of electronic component 120 can range from about 190 μm to about 210 μm. Electronic component 120 can sense external light or emit light outside. In some examples, electronic component 120 can perform various calculations and control processing, store data, remove noise from an electrical signal, or transmit/receive radio frequencies.

FIG. 2F shows a cross-sectional view of electronic device 100 at a later stage of manufacture. In the example shown in FIG. 2F, encapsulant 160 can be provided on substrate 110, electronic component 120, internal interconnect 130, or substrate sidewall 150. In some examples, encapsulant 160 can cover or contact substrate 110, electronic component 120, internal interconnect 130, or substrate sidewall 150. In some examples, encapsulant 160 can contact the lateral sides of electronic component 120 and sloped side 150a of substrate side wall 150. In some examples, the top side of encapsulant 160 can be recessed from the top side of electronic component 120 (e.g., as illustrated in the right half of FIG. 2F) or can reach a level of the top side of electronic component 120 (e.g., as illustrated in the left half of FIG. 2F). In some examples, the top side of encapsulant 160 can be recessed from or reach the level of the top side 150b of substrate side wall 150. In some examples, transceiver 121 and component terminals 122 of electronic component 120 can be exposed through the top side of encapsulant 160.

In some examples, a portion of internal interconnect 130 can be exposed through the top side of encapsulant 160. Encapsulant 160 can cover a portion of internal interconnect 130. Encapsulant can be referred to as unmolded when a liquid material is deposited and cured without using a mold. In some examples, encapsulant 160 can comprise thermosetting mixture of polymeric resin (e.g., an epoxy resin or a phenol resin), a hardener, a carbon black, and a silica filler. In some examples, encapsulant 160 can comprise or be referred to as a mold compound, an epoxy, a resin, a sealant, a polymer, or an organic body. In some examples, encapsulant 160 can be filler-free, or can be filler-reinforced with filler particles, such as inorganic beads or particles like SiO2. In some examples, encapsulant 160 can be provided by transfer molding, liquid encapsulant molding, vacuum lamination, paste printing, film assist molding, or compression molding. Transfer molding can be a method in which a fluid resin is supplied from a gate (supply port) of a mold to a space between electronic component 120 and substrate sidewall 150 on substrate 110 and then cured. Liquid encapsulant molding can be a method in which liquid encapsulants are dispensed in a space between electronic component 120 and substrate sidewall 150 on substrate 110 and then cured. The thickness of encapsulant 160 can range from about 208 μm (micrometers) to about 230 μm. Encapsulant 160 can protect substrate 110, electronic component 120, or internal interconnects 130 from exposure to external elements or environments. Encapsulant 160 can rapidly dissipate the heat of electronic component 120 to the external side.

FIG. 2G shows a cross-sectional view of electronic device 100 at a later stage of manufacture. In the example shown in FIG. 2G, lid 180 can be provided on substrate sidewall 150. In some examples, lid 180 can be attached on substrate sidewall 150 through lid attach material 170 such as an adhesive, a film, or an epoxy. In some examples, lid attach material 170 can be provided on substrate sidewall 150 or a portion of encapsulant 160. In some examples, lid attach material 170 can reach or contact top side 150b of substrate sidewall 150, planar vertical side 151a of substrate sidewall dam 151, top side 151b of substrate sidewall dam 151, or a portion of encapsulant 160. In some examples, the contact area of lid attach material 170 can reach the portion of the encapsulant 160, as well as top side 150b, planar vertical side 151a or top side 151b. The contact area can also be referred to as an adhesion area or an interface. The interface between lid attach material 170 and encapsulant can extend over a portion of internal interconnect 130 such that a portion of internal interconnect 130 is within the footprint of the contact area. In some examples, lid attach material 170 can be spaced apart from transceiver 121 of electrical component 120 or internal interconnects 130. The thickness of lid attach material 170 can range from about 80 μm to about 130 μm.

Lid 180 can be attached to lid attach material 170. In some examples, lid 180 can comprise or be referred to as transmissive, translucent, or transparent, or can comprise glass or plastic. Since lid 180 is transmissive, light or other radiation signals can pass through lid 180 to or from transceiver 121. In some examples, lid 180 can comprise a glass lid with light shielding and AR (Anti-Reflective) coating. By light shielding coating with AR coated glass, electronic device 100 can reduce reflected light that causes flare. Cavity 115 can be defined by electronic component 120, encapsulant 160, lid attach material 170, and lid 180. Top side 150b, planar vertical side 151a and top side 151b of substrate sidewall 151 can also serve as a dam to limit the flow of lid attach material 170 to increase the thickness or cross-section area of lid attach material or to increase the contact area between lid attach material 170 and lid 180. Due to the step mold structure of substrate sidewall 150 and substrate sidewall dam 151, a height “H” or cross-section area of the epoxy fillet riding up the side of lid 180 can increase. The thickness of lid 180 can range from about 350 μm to about 450 μm. Lid 180 can allow optical signals to communicate with electronic component 120 and protect electronic component 120 from an external environment.

Electronic device 100 can enhance reliability and performance by holding lid 180 with lid attach material 170 having a greater contact area with substrate sidewall 150 and encapsulant 160. The increased contact area and fillet size of lid attach material 170 tend to prevent delamination and inhibit void extension by releasing stress between lid attach material 170 and lid 180. In some examples, encapsulant 160 can widen the area of contact under lid 180 (to increase contact width “W” or contact area of lid attach material 170). In some examples, the step mold structure or trench mold structure can increase epoxy fillet of lid attach material 170.

FIG. 2H shows a cross-sectional view of electronic device 100 at a later stage of manufacture. In the example shown in FIG. 2H, external interconnects 190 can be provided on substrate 110 (optional). External interconnects 190 can be provided by being plated or deposited on substrate bottom terminal 112b. External interconnects 190 can comprise or be referred to as conductive balls, conductive bumps, conductive pillars, and solder balls. In some examples, a flux can be provided on substrate bottom terminals 112b, solder balls can be dropped on the flux, and then the solder balls can be coupled to substrate bottom terminal 112b through a reflow process or a laser assisted bonding process. In some examples, external interconnects 190 can comprise Sn (tin), Ag (silver), Pb (lead), Cu (copper), Sn—Pb, Sn37-Pb, Sn95-Pb, Sn—Pb—Ag, Sn—Cu, Sn—Ag, Sn—Au, Sn—Bi, or Sn—Ag—Cu. In some examples, the thickness or the diameter of external interconnects 190 can range from about 400 μm to about μm mm. External interconnects 190 can serve to couple electronic device 100 to an external device. In some examples, the external interconnects 190 can be omitted, and thus electronic device 100 can be of LGA (Land Grid Array) type. After this process, a singulation process of sawing substrate 110 and substrate sidewall 150 can be performed.

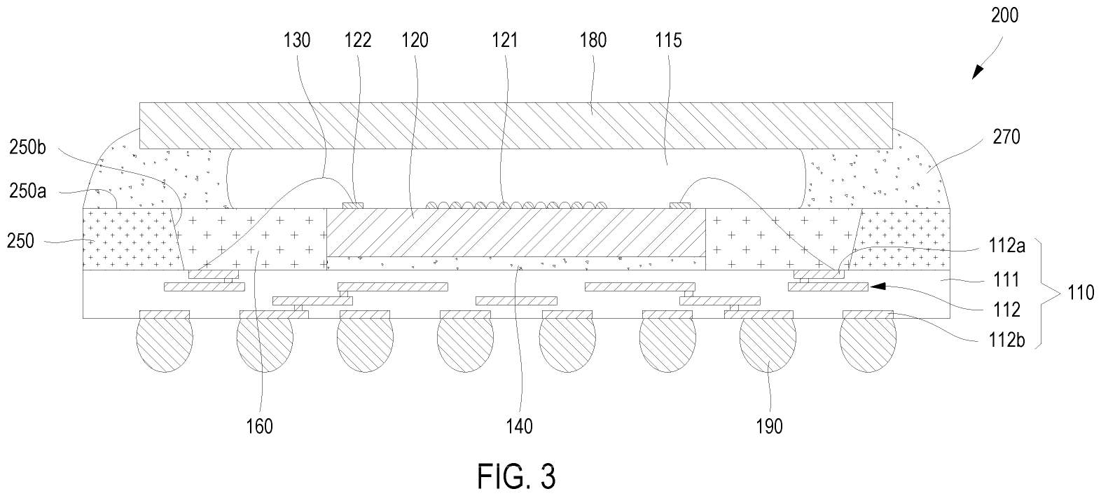

FIG. 3 shows a cross-sectional view of an example semiconductor device or electronic device 200. Electronic device 200 shown in FIG. 3 can be similar to electronic device 100 shown in FIG. 1. Electronic device 200 can include sloped side 250a and planar top side 250b. In some examples, the top side of encapsulant 160 can be recessed from top side 250b of substrate sidewall 250. In some examples, lid attach material 170 can contact or attach to top side 250b of substrate sidewall 250 and the top side of encapsulant 160. In some examples, the contact or adhesion area of lid attach material 270 can be increased to a portion of encapsulant 160, as well as to top side 250b of substrate sidewall 250. In some examples, the portion of encapsulant 160 can also increase the contact or adhesion area between lid attach material 270 and lid 180.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device comprising:
a substrate;
a substrate sidewall over a side of the substrate;
an electronic device over the side of substrate and adjacent the substrate sidewall;
an internal interconnect coupled to the electronic device and extending between the electronic device and the substrate sidewall;
an encapsulant covering the internal interconnect between the electronic device and the substrate sidewall;
a lid attach material over the substrate sidewall and the encapsulant; and
a lid coupled to the encapsulant and the substrate sidewall by the lid attach material;
wherein a cavity is defined between a bottom side of the lid and a top side of the electronic device.

2. The electronic device of claim 1, wherein the substrate sidewall comprises a dam protruding from a ledge of the substrate sidewall.

3. The electronic device of claim 2, wherein the lid attach material contacts a top side of the dam, a lateral side of the dam, the ledge of the substrate sidewall, and a top side of the encapsulant.

4. The electronic device of claim 1, wherein the substrate sidewall is a molded compound having a filler material, and wherein the encapsulant is a filler-free material.

5. The electronic device of claim 4, wherein the encapsulant is unmolded.

6. The electronic device of claim 1, wherein the internal interconnect comprises wire coupled to the top side of the electronic device and coupled to the substrate.

7. The electronic device of claim 1, wherein the substrate comprises a printed circuit board.

8. The electronic device of claim 1, wherein the lid is transmissive.

9. The electronic device of claim 1, wherein the cavity is defined by the bottom side of the lid, the top side of the electronic device, a top side of the encapsulant, and an inner side of the lid attach material.

10. The electronic device of claim 1, wherein the cavity is isolated from the substrate sidewall.

11. An electronic device comprising:
a substrate;
a substrate sidewall over a side of the substrate, the substrate sidewall comprising a dam protruding from the substrate sidewall away from the substrate;
an electronic component over the side of substrate and adjacent the substrate sidewall;
an encapsulant between the electronic device and the substrate sidewall;
a lid attach material over the substrate sidewall and the encapsulant; and
a lid coupled to the encapsulant and the substrate sidewall by the lid attach material;
wherein a cavity is defined between the lid and the electronic device.

12. The electronic device of claim 11, wherein the lid attach material contacts a top side of the dam, a vertical side of the dam, a top side of the substrate sidewall, and a side of the encapsulant.

13. The electronic device of claim 11, wherein the cavity is isolated from the substrate sidewall.

14. The electronic device of claim 11, further comprising a wire coupling the electronic component to the substrate, wherein the encapsulant covers the wire between the electronic component and the substrate sidewall.

15. The electronic device of claim 14, wherein an interface between the lid attach material and the encapsulant extends over the wire.

16. The electronic device of claim 11, wherein a fillet of the lid attach material extends from the dam to a lateral sidewall of the lid.

17. A method of manufacturing an electronic device, comprising:
providing a substrate;
providing a substrate sidewall over a side of the substrate;
providing an electronic component over the side of the substrate and adjacent the substrate sidewall;
providing an encapsulant between the substrate sidewall and the electronic component;
providing a lid attach material over the substrate sidewall and the encapsulant; and
providing a lid coupled to the substrate sidewall and the encapsulant by the lid attach material.

18. The method of claim 17, further comprising providing an internal interconnect between the substrate sidewall and the electronic component.

19. The method of claim 17, wherein the substrate sidewall comprises a dam that contacts the lid attach material, wherein a fillet of the lid attach material extends from the dam to a lateral wall of the lid.

20. The method of claim 17, wherein the substrate sidewall is a molded compound having a filler material, and wherein the encapsulant is a filler-free material.
